(19) United States
(12) Patent Application Publication
(10) Pub. No.: US 2011/0290990 A1
(43) Pub. Date: Dec. 1, 2011

(54) CONSTRUCTION UNIT, COMPRISING A LIGHT DETECTOR, AND A PROCESS TO ASSEMBLE SUCH CONSTRUCTION UNIT TO A CARRIER, SUCH AS PRINTED CIRCUIT CARD

(75) Inventor: Hans Göran Evald Martin, Delsbo (SE)

(73) Assignee: SENSEAIR AB, Delsbo (SE)

(21) Appl. No.: 13/143,763

(22) PCT Filed: Feb. 8, 2010
(86) PCT No.: PCT/SE2010/050144

§ 371 Date: Jul. 8, 2011

(30) Foreign Application Priority Data
Feb. 12, 2009 (SE) 0900178-5

(51) Int. Cl. H01L 31/12; H01L 31/18

(52) U.S. Cl. 250/226; 250/216; 438/65; 257/E31.095

(57) ABSTRACT

The present invention embraces a construction unit comprising a light detector and mountable to a carrier, such as a printed circuit card, and where said construction unit is adapted to be includable in a gas sensor-related arrangement. Said construction unit is assigned a plurality of first connection devices, which connection devices are adapted and distributed along a first surface portion of said construction unit for an electric connection facility to second connection devices related to said carrier. Said construction unit is adapted attachable to or placeable in the vicinity of a translucent recess formed in said carrier for the formation of an aperture. An optoelectric sensor is tightly placed against one side surface of said carrier while a first light-generating means is orientable, preferably as an individual unit, at an adapted distance from or along the other and opposite side surface of the carrier. Said optoelectric sensor shall be protected by a transparent, or in any case partly transparent, cover plate alternatively a filter.

### TECHNICAL FIELD OF THE INVENTION

The present invention relates in the first place generally to a construction unit comprising a light detector and in the second place to a process to assemble a construction unit to one side surface of a carrier.

More particularly, the present invention teaches that such a discrete construction unit shall be able to be mountable to a carrier, such as a printed circuit card, in the form of a printed board, a printed board assembly or the like, in a known way and be electrically connected with electric and/or electronic circuits, distributed to such a printed circuit card.

Said construction unit is even more specially adapted to be includable in a gas sensor-related arrangement, where such a complete arrangement, among other things, is adapted to embrace a first means generating a light, a second means receiving a light, as well as a third means for the formation of and defining an optical gauge length between said first and second means, through a gas sample.

Such an arrangement requires for its function a control unit, having appurtenant calculation and memory circuits as well as having a central processing unit, where said first and/or second means shall, in accordance with the provisions of the invention, be adapted to form said discrete construction unit. The control unit may advantageously co-operate with a display unit or another circuitry.

Such a construction unit formed as a discrete unit shall then be assigned a plurality of first connection devices, which first connection devices are adapted and distributed along a first surface portion or the like of said construction unit for an electric connection facility to second connection devices related to said carrier, or primarily a utilized printed circuit card being under preparation.

Since the present invention also intends to embrace a process to assemble such a construction unit to a carrier, such as in the form of a printed circuit card, it should also be mentioned that the present invention intends to offer a new discrete construction unit, which, in the same way as for other corresponding discrete elements, shall be attachable to a printed circuit card and be electrically connected to electric contact devices related to the printed circuit card in a production line for a printed circuit manufacturing, where each one of these produced printed circuit cards will be able to carry a plurality of such discrete elements.

The present invention should be regarded as a further development of the gas sensor-related arrangement that is shown in more detail and disclosed in the Swedish patent application 08 02562-9, filed 12 Dec. 2008.

The contents in said patent application should thereby be considered to be a part of this application for clarifying expressions and definitions utilized here.

The invention should primarily have an application in construction units that contain an optoelectric sensor and for an application in gas analysis, but it is evident that the invention also may have other applications, such as in a pressure-sensitive sensor.

The present invention intends to be usable in measurements of the concentration of CO₂ in an air volume but also in concentration measurements of NOₓ, alcohol, CO or other gases active to IR radiation (infrared radiation).

Even if the subsequent description will illustrate the present invention as a discrete construction unit having an optoelectric sensor, there is nothing that prevents co-ordination of two or more optoelectric sensors and/or other sensors in one and the same construction unit.

Sensors of the relevant type have a sensitive surface area that is assigned to the sensor unit for a selected reaction component and orientated in and/or on the construction unit in order to form an opening there, and which sensitive surface area is exposable to the reaction component, such as light and pressure.

To the prior art, there belong also different processes and methods to form printed circuit cards and, via a “picking technique”, allow to apply and attach discrete components to these printed circuit cards to selected surface sections of one side surface of the printed circuit card.

In this respect, the present invention is based on a process for allowing to apply one or more discrete construction units to a carrier, such as a printed circuit card, where said carrier is adapted to, in several process steps, successively be processed toward a finished product or a semi-finished product, the carrier being assigned a number of recesses, in the form of vias, traversing the carrier, and where a selected discrete construction unit is adapted to become placed on one side of the printed circuit card adjacent to a selected recess and where the construction unit is adapted to contain a sensor unit.

### BACKGROUND OF THE INVENTION

Methods, arrangements, processes and designs related to of the above-mentioned technical field and nature are previously known in a plurality of different embodiments.

As examples of the background art and the technical field to which the invention relates, what is seen in the clause “Background of the Invention” in the above-mentioned Swedish patent application may be mentioned.

More particularly, what is shown and described in connection with FIG. 1 hereinafter also belongs to the prior art.

There, a construction unit that comprises a light detector and is easily mountable as a discrete component of a carrier, such as a printed circuit card, is shown and described, and where said construction unit is primarily adapted to be included in a gas sensor-related arrangement. Here, construction units of the relevant type are placed on “the upperside” of the printed circuit card and then on the same side as the first means generating a light.

A more detailed account of such a known construction unit is found hereinafter, under the subheading “Description of the known light-receiving construction, according to FIG. 1”.

To complete the known technique, reference is made to the construction unit “SMM100” that is marketed by Robert Bosh GmbH, P.O. 1342, 727 03 Reutlingen, Germany, and that in principle has the design shown and described in FIG. 1.

The construction unit could be used for allowing an IR light serving as a reaction component to pass holes formed in the printed board.

### SUMMARY OF THE PRESENT INVENTION

### Technical Problem

If attention is paid to the circumstance that the technical considerations that a person skilled in the relevant technical field has to do to be able to present a solution to one or more technical problems raised, are, on one hand, initially a necessary understanding of the measures and/or the sequence of measures that have to be taken, and on the other hand a necessary selection of the means that is/are required, then the subsequent technical problems would, in view of this, be relevant in the creation of the present subject matter of invention.

In view of the prior art concerning discrete components, their application to a printed circuit card and/or process therefor, such as it has been described above, it should be seen as a technical problem to be capable of realizing the significance of, the advantages associated with and/or the technical measures and considerations that will be required to, in a construction unit that comprises a detector and is mountable to a carrier, such as a printed circuit card, and where said construction unit is adapted to be includable in an arrangement activatable to a reaction component, where such an arrangement is adapted to embrace a first means and/or a second means and/or a third means, as well as a control unit, where said first and/or second means is/are adapted to form a construction unit, said construction unit being, as a discrete component, assigned a plurality of first connection devices, which connection devices are adapted and distributed along a first surface portion of said construction unit for an electric connection facility to second connection devices related to said carrier, be able to provide simpler design details for a discrete component equipped with a sensor that will be able to offer an increased precision, a simplified production and/or a more compact design of a produced printed circuit card.

In view of the prior art, such as it has been described above, it should be seen as a technical problem to be capable of realizing the significance of, the advantages associated with and/or the technical measures and considerations that will be required to, in a construction unit that comprises a light detector and is mountable to a carrier, such as a printed circuit card, and where said construction unit is adapted to be includable in a gas sensor-related arrangement, where such an arrangement is adapted to embrace a first means generating a light, a second means receiving a light, as well as a third means for the formation of and defining an optical gauge length between said first and second means, through a gas sample, as well as a control unit, where said first and/or second means is/are adapted to form said construction unit, said construction unit being assigned a plurality of first connection devices, which connection devices are adapted and distributed along a first surface portion of said construction unit as a discrete component for an electric connection facility to second connection devices related to said carrier, be able to provide simpler design details for a discrete component equipped with a light sensor that will be able to offer an increased precision in relation to the known technique provided in FIG. 1 as well as in addition be adaptable to known production processes and offer a compact design of a thus produced printed circuit card having applied discrete components.

There is a technical problem to be capable of realizing the significance of, the advantages associated with and/or the technical measures and considerations that will be required to, for the construction unit, allow to provide a utilization of general, in principle application-neutral, components.

There is a technical problem to be capable of realizing the significance of, the advantages associated with and/or the technical measures and considerations that will be required to allow to create such conditions in order to, in this application, be able to utilize inexpensive optical filter materials and with requirements of smaller surface extension than what previously has been possible to provide.

There is a technical problem to be capable of realizing the significance of, the advantages associated with and/or the technical measures and considerations that will be required to allow to create conditions adapted to production so that a carrier or a printed circuit card easily shall be formable to form an optical diaphragm or aperture adapted to generated light, through a small recess formed in said carrier and traversing the carrier.

There is a technical problem to be capable of realizing the significance of, the advantages associated with and/or the technical measures and considerations that will be required to, as a protective cover, such as for a utilized optoelectric sensor, allow to utilize a small plate of glass, mica, silicon and/or germanium or a corresponding optical transparent broad-band material.

There is a technical problem to be capable of realizing the significance of, the advantages associated with and/or the technical measures and considerations that will be required to allow to provide a flexibility to the manufacturer of printed circuit cards in the application of one or more construction units, in that a selected design of the printed circuit card can offer a formation of one or more small traversing recesses, to be covered by the respective construction unit.

There is a technical problem to be capable of realizing the significance of, the advantages associated with and/or the technical measures and considerations that will be required to be offered a possibility of, in case need arises therefor, being able to select also more expensive optical filters having optical narrow-band transparency.

There is a technical problem to be capable of realizing the significance of, the advantages associated with and/or the technical measures and considerations that will be required to allow to provide a construction unit, in the form of a discrete unit, which is easily packable and directly adapted to an application to one side surface of a printed circuit card and then the side surface that is faceable from or side-related to the first means generating an IR light and a direction of its reaction component.

There is a technical problem to be capable of realizing the significance of, the advantages associated with and/or the technical measures and considerations that will be required to allow said construction unit to be adapted with the smallest possible dimensions and be attachable to or placeable in the vicinity of a translucent recess formed in said carrier or printed circuit card for the formation of an aperture serving as a diaphragm and connectable to contact devices assigned to the carrier.

There is a technical problem to be capable of realizing the significance of, the advantages associated with and/or the technical measures and considerations that will be required to allow an optoelectric sensor to be placed on or next to one side surface of said carrier, while said first light-generating means shall be orientable at an adapted distance from or along the other and opposite side surface of the carrier.

There is a technical problem to be capable of realizing the significance of, the advantages associated with and/or the technical measures and considerations that will be required to allow said optoelectric sensor and the light-sensitive surface area thereof to be protected by a transparent, or in any case partly transparent, cover plate, placed on one and/or the other side surface of the carrier or printed circuit card.

There is a technical problem to be capable of realizing the significance of, the advantages associated with and/or the technical measures and considerations that will be required to allow said cover plate to be orientated and dimensioned to only cover said recess, and that the cover plate should be directly or indirectly attached to one and/or the other side surface of the carrier or printed circuit card.

There is a technical problem to be capable of realizing the significance of, the advantages associated with and/or the technical measures and considerations that will be required to allow such a cover plate to be assigned the form of a filter, such as an optical interference filter.

There is a technical problem to be capable of realizing the significance of, the advantages associated with and/or the technical measures and considerations that will be required to allow a surface extension assigned to said recess, in a plane connecting to one side surface of the carrier, to be delimited to a diaphragm opening, having a surface extension that is less than the surface extension of the total light-sensitive surface extension or surface area of the optoelectric sensor.

There is a technical problem to be capable of realizing the significance of, the advantages associated with and/or the technical measures and considerations that will be required to allow the surface extension of the recess in the carrier to be adapted to a central surface section of the surface extension of the light-sensitive sensor.

There is a technical problem to be capable of realizing the significance of, the advantages associated with and/or the technical measures and considerations that will be required to allow said recess to have a cross-sectional area between 0.2 and 20 mm², such as about 1 to 5 mm².

There is a technical problem to be capable of realizing the significance of, the advantages associated with and/or the technical measures and considerations that will be required to allow said recess to have a length through the carrier, connecting to the propagation direction of the light through the carrier, between 0.1 and 5 mm, such as 1 to 2 mm.

There is a technical problem to be capable of realizing the significance of, the advantages associated with and/or the technical measures and considerations that will be required to allow to provide simple means for creating a thermal insulation and/or a sealing insulation around the utilized optoelectric sensor and against the carrier, for a more thermally stable measurement and/or air seal.

There is a technical problem to be capable of realizing the significance of, the advantages associated with and/or the technical measures and considerations that will be required to allow said recess to be assigned the form of a via going through the carrier and where the surface section forming and enclosing the recess is treated to exhibit high-reflective properties.

There is a technical problem to be capable of realizing the significance of, the advantages associated with and/or the technical measures and considerations that will be required to allow to provide a process for allowing to apply one or more discrete construction units to a carrier, such as a printed circuit card, where said carrier is adapted to, in several process steps, successively be processed toward a finished product or a semi-finished product, the carrier being assigned a number of recesses, in the form of vias, traversing the carrier, and where a selected discrete construction unit is adapted to become placed on one side of the printed circuit card adjacent to a selected recess and where the construction unit is adapted to contain a sensor unit, and in that connection allow to teach that a surface area that is assigned to the sensor unit and sensitive to the selected reaction component becomes orientated in the construction unit and connecting to a formed opening in the construction unit, adapted to co-operate with said via, whereupon the discrete construction unit is attached to a first surface area in one of the sides of the carrier, and that said recess and/or via is/are adapted to serve as an open channel toward said sensitive surface area, in order to, from the other side of the carrier, convey a reaction component for said sensitive surface area.

There is a technical problem to be capable of realizing the significance of, the advantages associated with and/or the technical measures and considerations that will be required to, as a selected reaction component, allow to select a light, an IR light.

There is a technical problem to be capable of realizing the significance of, the advantages associated with and/or the technical measures and considerations that will be required to, as a selected reaction component, allow to select a pressure, a positive pressure or a negative pressure.

There is a technical problem to be capable of realizing the significance of, the advantages associated with and/or the technical measures and considerations that will be required to allow said opening to be covered by a transparent cover plate.

There is a technical problem to be capable of realizing the significance of, the advantages associated with and/or the technical measures and considerations that will be required to allow said opening to be covered by an interference filter.

There is a technical problem to be capable of realizing the significance of, the advantages associated with and/or the technical measures and considerations that will be required to allow an interference filter to be adapted to be applied to cover the via, at its opening toward the second surface area.

The Solution

In that connection, the present invention starts out from the known technique provided by way of introduction and is based on a construction unit that comprises a light detector, is formed as a discrete component, and is mountable to a carrier, and where said construction unit is adapted to be includable in a gas sensor-related arrangement, where such an arrangement is adapted to embrace a first means generating a light, a second means receiving a light, as well as a third means for the formation of and defining an optical gauge length between said first and second means, through a gas sample, as well as a control unit, where said first and/or second means is/are adapted to be able to form said construction unit, said construction unit being assigned a plurality of first connection devices, which connection devices are adapted and distributed along a first surface portion of said unit for an electric connection facility to second connection devices related to said carrier.

In order to be able to solve one or more of the above-mentioned technical problems, the present invention particularly teaches that the thus known technique shall be supplemented by allowing said construction unit to be adapted attachable to or placeable in the vicinity of a translucent recess formed in said carrier for the formation of an aperture adapted to a diaphragm, that the construction unit, including a built-in optoelectric sensor, shall be placed tightly to one side surface of said carrier while said first light-generating means shall be orientable, at an adapted distance from or along the other and opposite side surface of the carrier, and that said optoelectric sensor and the light-sensitive surface area thereof shall be protected by a transparent, or in any case semitransparent, cover plate or an optical filter.

As proposed embodiments, falling within the scope of the fundamental idea of the present invention, moreover it is taught that said cover plate shall be orientated near and dimensioned to cover said recess, and that such a cover plate should directly or indirectly be attached to one and/or the other side surface of the carrier.

Said cover plate may advantageously be assigned the form of a wave-length selective filter, such as an optical interference filter, a colour filter and/or a diffractive element.

Particularly, it is taught that a surface extension assigned to said recess, in a plane connecting to one side surface of the carrier, shall be delimited to or be larger a diaphragm opening, having a surface extension adapted to correspond to, be larger or be smaller than a surface extension of the total light-sensitive surface extension of the optoelectric sensor.

The surface extension of the recess in the carrier should primarily be adapted to a central surface section of the light-sensitive surface extension.

Said recess may advantageously have a cross-sectional area between 0.2 and 20 mm², such as about 1 to 5 mm².

It is further suggested that said recess will be able to have a length through the carrier, connecting to the propagation direction of the light, between 0.1 and 5 mm, such as 1 to 2 mm.

Furthermore, it is provided a possibility of being able to heat-insulate and/or seal the optoelectric sensor against the carrier for a more stable measurement.

The invention suggests furthermore that a process for allowing to apply one or more discrete construction units to a carrier, such as a printed circuit card, where said carrier is adapted to, in several process steps, successively allow to be processed toward a finished product or a semi-finished product, the carrier being assigned a number of recesses traversing the carrier, and where a selected discrete construction unit is adapted to become placed on one side of the printed circuit card adjacent to a selected recess and where the construction unit is adapted to contain a sensor unit.

Particularly, it is taught that a sensitive surface area that is assigned to the sensor unit, orientated in the construction unit, and connecting to a formed opening in the construction unit, shall be adapted to co-operate with said recess.

The discrete construction unit is attached tightly to a first surface area of the carrier, said recess being adapted to serve as an open channel toward said sensitive surface area, in order to, from the other side of the carrier, convey a reaction component for said sensitive surface area.

Furthermore, it is taught that as a reaction component a light, an IR light, is selected, or as a reaction component a pressure, such as a positive pressure or negative pressure, is selected.

Said opening shall in a separate process step be covered by a transparent cover plate.

Said opening shall in a separate process step be covered by an interference filter.

Particularly, it is taught that the interference filter shall be adapted to be applied to cover the recess at its opening toward the second surface area.

Advantages
The advantages that foremost may be regarded as characteristic of the present invention and the special significative features provided thereby are that, in this way, conditions have been created in order to, in a construction unit that comprises a detector and is mountable as a discrete unit to a carrier, and where said construction unit is adaptable to be includable in an arrangement, where such an arrangement is adapted to be able to embrace a first means, a second means, as well as a third means, as well as a control unit having a display unit or the like, where said first and/or second means is/are adapted to form said construction unit, said construction unit being assigned a plurality of first connection devices, which connection devices are adapted and distributed along a first surface portion of said unit for an electric connection facility to second connection devices related to said carrier, allow to teach that said construction unit shall be adapted attachable tightly to or placeable in the vicinity of a recess that is formed in said carrier and permeable to a selected reaction component for the formation of an aperture, that the sensor shall be placeable tightly against one side surface of said carrier while said first means may be orientable, at an adapted distance from or along the other and opposite side surface of the carrier, and that the active surface area of said sensor shall be protected by a cover plate.

Such a discrete unit equipped with a sensor, in the form of a construction unit, offers a mounting to the printed circuit card from a side, offering a compact design and flexibility in the production.

What foremost may be regarded as characteristic of a construction unit, in accordance with the present invention, is defined in the characterizing clause of the appended claim 1, while a process step particularly provided for the invention is defined in the characterizing clause of the appended claim 10.

### BRIEF DESCRIPTION OF THE DRAWINGS

Prior art, in this technical field, and a presently proposed embodiment, having the significative features associated with the invention, as well as a process to allow to apply one or more discrete construction units to a carrier, will now, for the purpose of exemplifying, be described in more detail with reference to the appended drawing, wherein:

FIG. 1 shows, in a cross-section, a previously known construction unit, adjacent to a light-receiving means, mounted on a carrier in the form of a printed circuit card,

FIG. 2 shows, in a cross-section, a light-receiving means, in accordance with the provisions given according to the present invention, mounted tightly against a carrier, in the form of a printed circuit card,

FIG. 3 shows, on an enlarged scale, parts of the printed circuit card and a recess formed therein,

FIG. 4 lets show, in side view, and in section a construction unit equipped with a sensor, and

FIG. 5 lets schematically show a process with its different process steps and particularly a process step where one (or several) discrete construction unit is applied to a carrier, electrically connects the same to the contact device of the carrier and where the unit is surrounded by a thermally insulating layer.

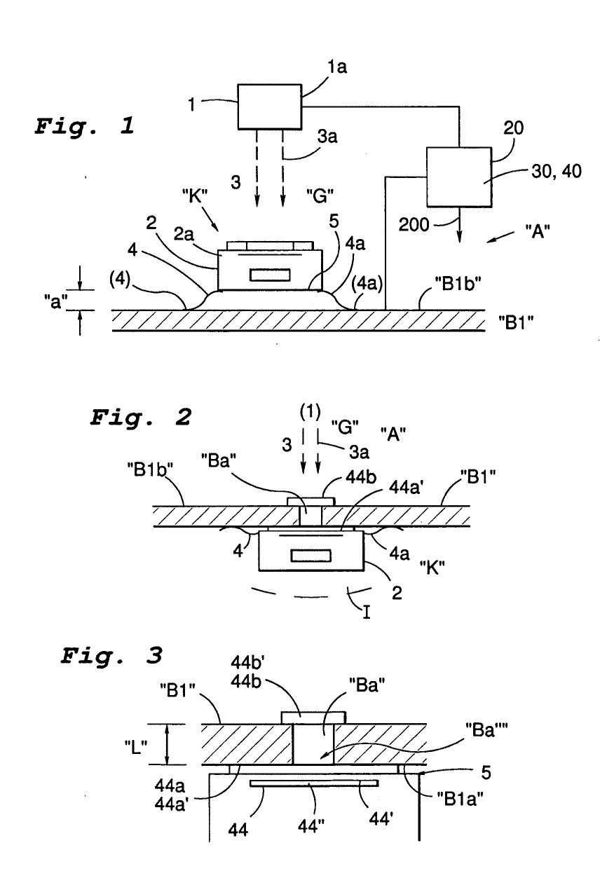

### DESCRIPTION OF THE KNOWN LIGHT-RECEIVING CONSTRUCTION ACCORDING TO FIG. 1.

A construction “K” unit comprising a light detector and mountable to a carrier “B1”, here illustrated as a printed circuit card, and where said construction unit is adapted to be includable in a gas sensor-related arrangement “A”, where such an arrangement is adapted to embrace a first means 1 generating a light, a second means 2 receiving a light, as well as a third means 3 for the formation of and defining an optical gauge length between said first 1 and second 2 means, through a gas sample “G”, as well as a control unit 20, having appurtenant calculation circuits 30 and memory circuits 40. Control units of the relevant type are well known and are therefore not described, neither a display unit, nor the corresponding circuitry, coupled to the control unit.

Said second means 2 is adapted to form said construction unit “K”, said construction unit being assigned a plurality of first connection devices 4, 4a, which connection devices are adapted and distributed along a first surface portion 5 of said construction unit for an electric connection facility to second connection devices (4), (4a) related to said carrier “B1”.

Via an output conductor 200, an evaluated spectral analysis is mediated to a display unit (not shown).

Here, it should be noted that the means 2 will become placed at a distance “a” (the length of the first connection devices 4, 4a) from the surface “B1b” of the carrier “B1”.

The first means 1 is placed over the second means 2 and over the carrier “B1”.

DESCRIPTION of a PRESENTLY PROPOSED EMBODIMENT

It should then by way of introduction be emphasized that in the subsequent description of a presently proposed embodiment, which has the significative features associated with the invention and which is elucidated by the figures shown in the appended drawings, we have selected terms and a particular terminology with the intention to thereby primarily allow to make evident the proper inventive idea.

It should, however, in this connection be taken into consideration that expressions selected here should not be seen as limiting solely to the terms utilized and selected here, but it should be understood that each term selected in this manner should be interpreted so that it, in addition, will be able to comprise all technical equivalents operating in the same or substantially the same way in order to, in this way, enable the achievement of the same or substantially the same intention and/or technical effect.

With a reference to the appended FIGS. 2, 3 and 4, in these figures, reference designations that correspond to the ones in FIG. 1 used for the same or similar details have been inserted.

Accordingly, FIGS. 2 and 3 schematically show and in detail the fundamental conditions for the present invention, and where the significative peculiarities associated with the invention have been made concrete, by the presently proposed embodiment described more in detail in the following.

Accordingly, FIG. 2 lets show that said construction unit “K” or the second means 2 is adapted attachable against and to or placeable in the vicinity of a translucent recess “Ba” formed in said carrier “B1”, for the formation of an aperture or diaphragm opening.

An optoelectric sensor, in the form of an IR detector 44, is placed against or next to one side surface “B1a” of said carrier “B1” while said first light-generating means 1 is orientable, for instance as an individual unit, at an adapted distance from the other and opposite side surface “B1b” of the carrier “B1”, and that said optoelectric sensor 44 is protected by a transparent, or in any case partly transparent, cover plate 44a, and/or or transparent cover plate 44b.

The first means 1 could very well consist of a discrete component, attached to the carrier “B1” on the same side as the second means 2 and in connection with a co-operation with a light guide 3 (not shown) applied to the side surface “B1b”.

Said cover plate 44a is orientated toward and dimensioned to cover said recess “Ba” from below, while the cover plate 44b is directly or indirectly attached to the side surface “B1b” of the carrier, where FIG. 3 primarily lets illustrate an attachment to the lower side surface “B1a”.

Said cover plate 44a and/or the cover plate 44b may be assigned the form of a filter, such as an optical interference filter 44a′, 44b′ for emitted beams of light 3a.

A surface extension assigned to said recess “Ba”, in a plane connecting to one side surface, “B1a” or “B1b”, of the carrier, is delimited to a diaphragm opening, having a surface extension “Ba” connecting to, being larger or being somewhat smaller than the surface extension of the total light-sensitive surface extension 44′ of the optoelectric sensor 44.

The surface extension “Ba” of the recess “Ba” in the carrier “B1” is adapted to a central surface section 44″ of the light-sensitive surface extension 44′.

Said recess “Ba” has a cross-sectional area “Ba” between 0.2 and 20 mm², such as about 1 to 5 mm².

Said recess “Ba” has a length “L” through the carrier, connecting to the propagation direction of the light 3a, between 0.1 and 5 mm, such as 1 to 2 mm.

Finally, the present invention offers a possibility of thermally insulating the unit 2 to the underside “B1a” of the carrier or printed circuit card “B1” via an encapsulation “I”, in order to offer a more thermally stable measurement.

Said recess “Ba” is assigned the form of a via going through the carrier “B1” and where the cylindrical surface section forming and enclosing the recess is treated to exhibit high-reflective properties as being covered by a gold coating.

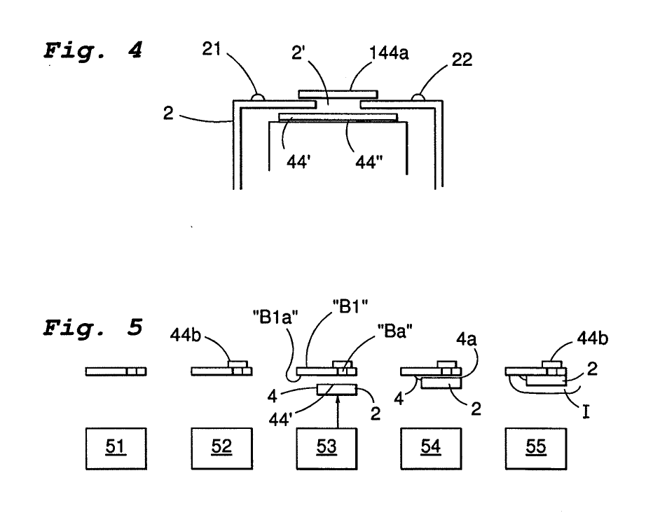

In FIG. 4, it is intended to illustrate an optoelectric sensor alternatively a pressure sensor built-in in the construction unit 2, which is formed with an opening 2′ and which opening may be covered by a cover plate 144a, which may be selected to have properties transparent to light, such as an optical interference filter, for a narrow-band transmission or a flexible cover plate to transmit pressure values occurring on the side surface “B1b”.

FIG. 5 lets illustrate a number of process steps for a manufacture of a printed circuit card having discrete components.

Accordingly, in a process step 52, an application of a narrow-band interference filter 44 is illustrated, a process step 53 illustrates a displacement of and an application of a second means 2 (or a first means 1) tightly against one side surface “B1a”, in a process step 54, an electric interconnection of the contact devices 4, 4a with contact devices assigned to the carrier is illustrated, and in a process step 55, an application of a thermal or air-proof encapsulation “I” of the unit 2 against the side surface “B1a” of the carrier “B1” is illustrated.

FIG. 5 intends thereby to schematically illustrate a process in order to, to a carrier, such as a printed circuit card, allow to tightly apply one or more discrete construction units 2, where said carrier is adapted to, in several process steps 51-55, successively be processed toward a finished product or a semi-finished product.

The carrier is assigned a number of recesses, in the form of vias “Ba”, traversing the carrier, and where a selected discrete construction unit is adapted to become placed against one side surface “Ba1” of the printed circuit card adjacent to a selected recess and the utilized construction unit 2 is adapted to contain a sensor unit.

Particularly, it is taught that a sensitive surface area 44′ that is assigned to the sensor unit, orientated in the construction unit, and connecting to a formed opening 2′ in the construction unit 2 is adapted to co-operate with said via, whereupon the discrete construction unit 2 is attached tightly against the first surface area in one of the sides surface.

A selected reaction component shall pass through the carrier.

Said recess and/or via is/are adapted to serve as an open channel toward said o sensitive surface area 44′ in order to, from the other side “B1b” of the carrier, convey a reaction component (3a) toward said sensitive surface area 44′ and preferably the central part 44″ thereof.

As a reaction component may then a light, an IR light be selected.

As a reaction component may then a one in the form of a positive pressure, a negative pressure and/or a difference pressure be selected.

Furthermore, it is taught that said opening 2′ may be covered by a thin foil 144a.

Said opening 2′ may as an alternative be covered by an interference filter 44b.

An interference filter may be adapted to be applied to cover the via “Ba” at its opening toward the second surface area “B1b”.

The construction unit 2 may be provided with seals 21, 22 in order to seal against the surface area “B1a”.

The invention is of course not limited to the embodiment given above as example, but may be subjected to modifications within the scope of the general idea according to the invention, illustrated in the subsequent claims.

Particularly, it should be taken into consideration that each unit and/or category shown can be combined with any other unit and/or category shown within the scope in order to be able to attain the desired technical function.

1. Construction unit comprising a light detector and mountable as a discrete unit to a carrier, such as in the form of a printed circuit card, and where said construction unit is adapted to be includable in a gas sensor-related arrangement, where such an arrangement is adaptable to embrace a first means generating a light, a second means receiving a light, as well as a third means for the formation of and defining an optical gauge length between said first and second means, through a gas sample, as well as a control unit, where said second means is adapted to form said construction unit, said construction unit being assigned a plurality of first connection devices, which connection devices are adapted and distributed along a first surface portion of said construction unit for an electric connection facility to second connection devices related to said carrier wherein said construction unit is adapted attachable to or placeable in the vicinity of a translucent recess formed in said carrier for the formation of an aperture, that the construction unit, including a built-in optoelectric sensor, is placeable on and against one side surface of said carrier while said first light-generating means is orientable, at an adapted distance from or along the other and opposite side surface of the carrier, and that said optoelectric sensor and the light-sensitive surface area thereof are protected by a transparent, or in any case partly or partially transparent, cover plate, alternatively a filter.

2. Construction unit comprising a light detector according to claim 1, wherein said cover plate is orientated near the side surface of the carrier and dimensioned to cover said recess, and that the cover plate is directly or indirectly attached to one and/or the other side surface of the carrier.

3. Construction unit comprising a light detector according to claim 1, wherein said cover plate is assigned the form of an optical interference filter.

4. Construction unit comprising a light detector according to claim 1, wherein a surface extension assigned to said recess, in a plane connecting to one side surface of the carrier, is delimited to a diaphragm opening, having a surface extension connecting to, being larger or being somewhat smaller than the surface extension of the total light-sensitive surface area of the optoelectric sensor.

5. Construction unit comprising a light detector according to claim 4, wherein the surface extension of the recess in the carrier is adapted to a central surface section of the light-sensitive surface area.

6. Construction unit comprising a light detector according to claim 1, wherein said recess has a cross-sectional area between 0.2 and 20 mm², such as about 1 to 5 mm.

7. Construction unit comprising a light detector according to claim 1, wherein said recess has a length through the carrier, connecting to the propagation direction of the light, between 0.1 and 5 mm.

8. Construction unit comprising a light detector according to claim 1, wherein a thermal coverage is adapted to surround said second means to a side surface for the carrier.

9. Construction unit comprising a light detector according to claim 1, wherein said recess is assigned the form of a via going straight through the carrier and where the surface section forming the via is treated to exhibit high-reflective properties.

10. Process for allowing to apply one or more discrete construction units according to claim 1 to a carrier wherein said carrier is adapted to, in several process steps, successively be processed toward a finished product or a semi-finished product, the carrier being assigned a number of recesses traversing the carrier, and where a selected discrete construction unit is adapted to become placed on one side of the printed circuit card adjacent to a selected recess and where the construction unit is adapted to contain a sensor unit, wherein a sensitive surface area that is assigned to the sensor unit, orientated in the construction unit, and connecting to a formed opening in the construction unit is adapted to co-operate with said recess, whereupon the discrete construction unit is attached to a first surface area of the carrier, and that said recess is adapted to serve as an open channel toward said sensitive surface area in order to, from the other side surface of the carrier, allow to convey a component for and toward said sensitive surface area, for a reaction in the surface area.

11. Process according to claim 10, wherein an IR light is selected as component.

12. Process according to claim 10, wherein a pressure, a positive pressure, a negative pressure or a difference pressure is selected as component.

13. Process according to claim 10, wherein said open channel is covered by a transparent cover plate.

14. Process according to claim 10, wherein said open channel is covered by an interference filter.

15. Process according to claim 10, wherein an interference filter is adapted to be applied to cover the open channel at its opening facing toward the second surface area.
